(19) United States
(12) Patent Application Publication
(10) Pub. No.: US 2018/0087324 A1
(43) Pub. Date: Mar. 29, 2018

(54) Polycrystalline Diamond Compact Cutters Having Metallic Coatings

(71) Applicant: Wenhui Jiang, Pearland, TX (US)

(72) Inventor: Wenhui Jiang, Pearland, TX (US)

(21) Appl. No.: 15/421,082

(22) Filed: Jan. 31, 2017

Related U.S. Application Data
(60) Provisional application No. 62/400,922, filed on Sep. 28, 2016.

(51) Int. Cl. E21B 10/567; C23C 14/18

(52) U.S. Cl. CPC E21B 10/567; C23C 14/18

(57) ABSTRACT

Polycrystalline diamond compact cutter with a metallic coating is disclosed. The coating covers the whole exterior surfaces of polycrystalline diamond table and may extend over partially or completely the exterior surfaces of a cemented carbide body substrate. The coating may have a metallurgical bonding with the polycrystalline diamond compact cutter, which is characterized by the formation of a carbide during deposition processes, heat treatments, or brazing operations. The coating may be a single layer or multilayer coating. The coating metallic material adjacent to the polycrystalline diamond compact cutter is the carbide-forming metals selected from Ti, Nb, Zr, V, Ta, Hf, Cr, W, Mo, or the alloys containing any of these metals. The outer layer of a multilayer coating consists of oxidation-resistant metals or alloys. Coating processes utilize physical vapor deposition, chemical vapor deposition, thermoreactive deposition and diffusion, electrolytic plating, electroless plating, any deposition methods, or their combinations.

### CROSS-REFERENCE TO RELATED APPLICATION

This application claims the benefit of U.S. Provisional Patent Application Ser. No. 62/400,922, filed on Sep. 28, 2016, titled “Hard Material Compacts Having Carbide/Nitride/Boride-Forming Metal Coatings,” the disclosure of which is incorporated herein in its entirety by this reference.

### BACKGROUND OF THE INVENTION—PRIOR ART

The following is a tabulation of some prior arts that presently appear relevant:

U.S. Patents

| Patent Number | Kind Code | Issue Date | Patentee |
|---|---|---|---|
| 3356473 | A | 1967 Dec. 5 | Hull et al. |
| 3650714 | A | 1972 Mar. 21 | Farkas |
| 3957461 | A | 1976 May 18 | Lindstrom et al. |
| 3929432 | A | 1975 Dec. 30 | Caveney |
| 3984214 | A | 1976 Oct. 5 | Pratt et al. |
| 6663682 | B2 | 2003 Dec. 16 | Baldoni et al. |
| 4399167 | A | 1983 Aug. 16 | Pipkin |
| 5024680 | A | 1991 Jun. 18 | Chen et al. |
| 5049164 | A | 1991 Sep. 17 | Horton et al. |
| 4738689 | A | 1988 Apr. 19 | Gigl etal. |
| 5529805 | A | 1996 Jun. 25 | Iacovangelo et al. |
| 5626909 | A | 1997 May 6 | Iacovangelo |
| 4605343 | A | 1986 Aug. 12 | Hibbs et al. |
| 5833021 | A | 1998 Nov. 10 | Mensa-Wilmot et al. |

U.S. Patent Application Publications

| Publication Nr. | Kind Code | Publication Date | Applicant |
|---|---|---|---|
| 20100206941 | A1 | 2010 Aug. 19 | Egan et al. |
| 20120114442 | A1 | 2012 May 10 | Johansson et al. |
| 20130287507 | A1 | 2013 Oct. 31 | Lind et al. |
| 20120103697 | A1 | 2012 May 3 | DiGiovanni |

Foreign Patent Documents

| Foreign | Country | | | |
|---|---|---|---|---|
| Doc. Nr | Code | Kind Code | Publication Date | Patentee |
| 0328583 | EP | B1 | 1995 Aug. 30 | Chen et al. |

The present disclosure relates to polycrystalline diamond compact (PDC) cutter used in various cutting, grinding, as well as drilling tools such as drilling bits and reamers for earth exploration and production. More specifically, the present disclosure relates to coatings of metallic materials which are applied to the polycrystalline diamond (PCD) surfaces of the PDC cutter to protect the PCD layer from thermal damages during brazing operations and cutting applications, so as to enhance the cutter's performance and operating life.

PDC cutters are well known in prior arts. They comprise a layer or “table” of PCD materials as a cutting element and a cemented carbide material body as a cutter substrate. They are typically cylindrical in shape. The PDC cutters are formed by sintering and bonding together relatively small diamond grains under conditions of high temperature and high pressure in the presence of a catalyst (for example, cobalt, nickel, iron, or alloys or mixtures thereof) to form a table of PCD materials on a cutter substrate. These processes are often referred to as high-temperature/high-pressure (HTHP) processes. The cutter substrate may comprise a cemented carbide material such as cobalt-sintered tungsten carbide. In such the instances, cobalt (or other catalyst material) in the cutter substrate may diffuse into the diamond grains during sintering and serve as the catalyst material for forming the intergranular diamond-to-diamond bonds, and the resulting diamond table, from the diamond grains. In other methods, powdered catalyst material may be mixed with the diamond grains prior to sintering the grains together in an HTHP process.

Alternatively, a PDC cutter can be formed by brazing an unbacked PCD onto a cemented carbide material substrate. The unbacked PCD can be formed by sintering individual diamond particles together in an HTHP process in the presence of a catalyst/solvent that promotes diamond-diamond bonding, as described previously.

It is common practice to braze PDC cutters as cutting elements onto various tools such as drilling bits and reamers. But, the PDC cutters have poor brazing capability and the bonding strengths are low. In addition, tungsten carbide (in a sintered tungsten carbide substrate), diamond (in a PCD table), and cobalt (in both sintered tungsten carbide substrate and PCD table) in the PDC cutters have a tendency to be oxidized and degrade during brazing operations or cutting applications where significant heat is generated. Especially, diamond is vulnerable in air or an oxygen containing environment at high temperatures, and it tends to be oxidized and graphitize. As a result, the PDC cutters may suffer premature failure.

In fact, it has been recognized that diamond particles degrade and lose during brazing operations and cutting applications when they are embedded in grinding, abrading, or cutting sections of various tools. These problems are commonly addressed by coating the diamond particles with metals or alloys that bond chemically to the particles, and alloy to the bond matrix. Various coatings of metals and alloys in single or multiple layers on the diamond particles are developed in order to enhance bond retention, improve high temperature oxidation resistance, suppress high temperature graphitization, and like benefits. Such coatings are especially useful when fine-grain diamond grits are employed in the various tools. Typical arts in this single diamond grain coating endeavor include U.S. Pat. Nos. 3,356,473 A, 3,650,714 A, 3,957,461 A, 3,929,432 A, 3,984,214 A, 6,663,682 B2, 4,399,167 A, 5,024,680 A, and U.S. Appl. Pat. No. 2010/0,206,941 A1.

Application of coating onto PCD materials and PDC cutters also receives much attentions. It is an effective approach for improving processing capabilities and properties of the PCD materials and the PDC cutters. Various coatings of metals, alloys, and compounds are developed for them in prior arts.

Metallic coatings on PCD materials are for improving their brazing capabilities. U.S. Pat. No. 5,049,164 A discloses PCD materials and diamond crystals with multilayer metal coatings for bonding them to a matrix, which comprise a first metal layer of a refractory metal, such as tungsten, a compliant metal layer of copper, and an outer metal layer of a refractory metal such as tungsten, so as to prevent thermal stress from damaging PCD or diamond. Metallic bonding layers of a metal, such as nickel, are placed between the tungsten and copper layers for improved bonding. The method of manufacturing multilayer metal coatings comprises applying the inner metal layer by chemical vapor deposition (CVD), applying the first bonding layer metal by electrolytic deposition, applying the compliant layer metal by electrolytic deposition, applying the second bonding layer by electrolytic deposition and applying the outer layer by chemical vapor deposition. A superabrasive tool element comprises a coated diamond product bonded either to a matrix comprising tungsten carbide or iron powder or to a cemented tungsten carbide support.

European Pat. No. 0,328,583 B1 relates to a thermally stable PCD (TSPCD) having a metal coating for improving brazing capability and enhancing its bonding strength to a support structure such as a drill bit, wherein the TSPCD refers to as a leached PCD. The TSPCD has a double layer coating including an outer metal portion chemically bonded to a support by means of a metallurgical bond and an inner carbide portion chemically bonded to the diamond element by an atom to atom bond between the carbon of the diamond and the carbide layer. The double layer coating consists of tungsten/titanium, tungsten/chromium or nickel/titanium. The coating has a thickness of 10 μm-30 μm, which is obtained by CVD or fused salt deposition. The coating covers at least the surfaces in contact with the matrix.

Metallic coatings on PCD materials are also for protecting them from oxidation during brazing operations. U.S. Pat. No. 4,738,689 A discloses a coating on porous self-bonded polycrystalline diamond compacts, hereinafter termed “porous PCD”, to improve their oxidation resistance. The porous PCD has a network of interconnected empty pores dispersed throughout, and contains less than about 3% non-diamond phase. It is a kind of TSPCD. All of the exterior surfaces of the porous PCD is enveloped with a continuous coating which is effective under metal bond fabrication conditions, so that oxidation of the diamond in the compact does not exceed a threshold level whereat loss of diamond properties of the compact occurs. Metal bond fabrication conditions comprehend an atmosphere containing oxygen or water vapor. Metal coatings are preferred, especially in coating thicknesses in excess of about 8 μm, and applied by a CVD process. The metal coating is selected from the group consisting of nickel, copper, titanium, iron, cobalt, chromium, tantalum, tungsten, niobium, zirconium, vanadium, molybdenum, and alloys, compounds, as well as mixtures including titanium nitride or titanium carbide.

U.S. Pat. Nos. 5,529,805 A and 5,626,909 A disclose multilayer coating on unbacked tool compacts including PCD and polycrystalline cubic boron nitride (PCBN), which comprises a metal bonding layer and a protective layer, so as to enable the compacts to be brazed in an air environment to a tool support. The metal bonding layer comprises chromium or tungsten-titanium alloys, while the protective layer is selected from silver, copper, gold, palladium, platinum, nickel, and their alloys. Furthermore, the invention teaches heating the metal bonding layer to form carbide or nitride at the interface between the coating and the compact, and heating the protective layer to provide adhesion of the protective layer to the bonding layer.

As described above, the metallic coatings are applied to PCD mainly for improving its brazing capability. The PCD is freestanding without a supporting substrate of a cemented carbide material, whose brazing capability is notorious. In contrast, generally speaking, metals and alloys have an excellent brazing and welding capability, as they have an excellent wettability to brazing alloys. A metal/alloy coating on the PCD would improve definitely its brazing capability.

Thick metallic coatings on PDC cutters are used for dissipating heat during cutting application that would cause thermal damages of the PDC cutters, as a metal or alloy is a good heat conductor. U.S. Pat. No. 4,605,343 A discloses an improved PDC cutter with a cemented carbide substrate, which has a metallic heat sink layer with a thickness of between about 0.01 and 0.1 inches (0.254-2.54 mm) (thick coating) covering at least the outer diamond surfaces of the diamond layer. The heat sink layer is selected from the group consisting of copper, tungsten alloyed with cobalt, nickel, iron, and nickel phosphorus alloys. The heat sink layer is bonded to the diamond surfaces via a bonding medium comprising at least one intermediate layer of metal selected from the group consisting of molybdenum, tungsten, titanium, zirconium, and chromium. The heat sink layer is used to dissipate heat generated during cutting.

Compound coatings on PDC cutters are for improving mechanical properties such as toughness and/or wear resistance. U.S. Pat. No. 5,833,021 A discloses a surface enhanced PDC cutter having coating refractory material to increases operational life. The coating typically has a thickness in the range of between 0.1 μm and 30 μm and may be made from titanium nitride, titanium carbide, titanium aluminum nitride, boron carbide, zirconium carbide, chromium carbide, chromium nitride, or any of the transition metals or Group IV metals combined with either silicon, aluminum, boron, carbon, nitrogen, or oxygen. The coating can be applied using conventional plating or other physical or chemical deposition techniques. The coating is applied only to the cutting face of inserts to be brazed into a bit body to avoid interference of brazing by the coating which may not be wetted by some brazing alloys. The test results indicate that 2 μm thick TiN coating on a PCD table of a PDC cutter increased its cutting capability by 15%.

U.S. Appl. Pat. Nos. 2012/0,114,442 A1 and 2013/0,287,507 A1 disclose a cutting tool insert comprising a body of cemented carbide, cermet, ceramics, high speed steel, PCD or PCBN, and a hard and wear resistant coating. The coating compounds are zirconium aluminum nitride and a NaCl-structured complex metallic compound, respectively. The coatings have a thickness of between 0.5 μm and 10 μm which is applied by PVD for metal cutting application generating high temperatures.

U.S. Appl. Pat. No. 2012/0,103,697 A1 discloses an earth-boring tool PCD insert of having a protective coating disposed over the insert. The coating comprises a ceramic comprising boron, aluminum, and magnesium. The ceramic of boron, aluminum, and magnesium has a low coefficient of friction and a high hardness.

Refractory compounds such as carbide and nitrides have a high hardness and good wear resistance. But, they are not good at oxidation resistance at high temperatures. Refractory compound coatings may not improve oxidation resistance of a PCD and a PDC cutter significantly. Furthermore, bonding of the compound coating with the PCD and its cutter may not be metallurgical, and thus, its bonding strength is limited.

Although PDC cutters are very successful as a cutting element in drilling tools for earth exploration and production, their premature failure still affects performance and efficiency of the drilling tools. The protection of the PDC cutters from thermal damages during brazing and cutting application is still an urgent task.

The present disclosure has a primary objective that metallic material coatings are applied onto PDC cutters to protect them from thermal damages during brazing operations and cutting applications such as oxidation and graphitization of diamond, so as to prolong their service life. Another benefit of the metallic coatings would improve brazing capability of the PDC cutters, increase bonding strength, and avoid the cutter loss during service.

### SUMMARY OF THE INVENTION

The present disclosure relates to a polycrystalline diamond compact (PDC) cutter having a metallic material coating. The PDC cutter consist of a leached or unleached PCD table and a cemented carbide body substrate. The coating covers at least all of the exterior surfaces of the PCD table of the PDC cutter, and it may also extend over partially or entirely the exterior surfaces of the cemented carbide body. The coating consists of one layer or multilayers. The coating layer adjacent to the PDC cutter must be carbide-forming metals selected from Ti, Nb, Zr, V, Ta, Hf, Cr, W, Mo, or the alloys containing any of these metals. If the coating consists of multilayers, the outermost coating layer consists of metals or alloys having a good oxidation resistance, which is selected from Ni, W, Ta, Ti, Cr, Fe, Mo, Mn, Ag, Cu, Au, Pt, Pd, or the alloys containing at least one of these metals. Interface between the coating and the PDC cutter may be bonded metallurgically, which is characterized by formation of a carbide that is achieved either during deposition processes, additional heat treatments, or subsequent brazing operations when joining to a tool body. A metallic coating thickness is in a range of 0.04 μm-100 μm, preferably 0.1 μm-20 μm.

The coating processes comprise various deposition methods such as physical vapor deposition (PVD), chemical vapor deposition (CVD), thermoreactive deposition and diffusion (TD), electrolytic plating, electroless plating, or their combinations.

### BRIEF DESCRIPTION OF THE DRAWING

FIG. 1 is a schematic illustration of a cross sectional view of a cylindrical PDC cutter comprising a PCD table and a cemented carbide body substrate.

FIG. 2 is a schematic illustration of a cross sectional view of a cylindrical PDC cutter having a one-layer metallic coating over all of the exterior surfaces of the PCD table.

FIG. 3 is a schematic illustration of a cross sectional view of a cylindrical PDC cutter having a two-layer coating over all of the exterior surfaces of the PCD table, which comprises an inner layer of carbide-forming metals or alloys and an outer layer of oxidation-resistant metals or alloys.

FIG. 4 is a schematic illustration of a cross sectional view of a cylindrical PDC cutter having a one-layer metallic coating over all of the exterior surfaces of the PCD table and a part of the exterior surfaces of the cemented carbide body substrate.

FIG. 5 is a schematic illustration of a cross sectional view of a cylindrical PDC cutter having a one-layer metallic coating over all of the exterior surfaces of the PDC cutter including the PCD table and the cemented carbide body substrate.

FIG. 6 is a photograph of the PDC cutter with a two layer coating covering all of the exterior surfaces of the PCD table and the side surfaces of the sintered tungsten carbide substrate.

### DRAWING—REFERENCE NUMERALS

10 cemented carbide body substrate
12 PCD table
14 coating layer of carbide-forming metals/alloys
16 coating layer of oxidation-resistant metals/alloys

### DETAILED DESCRIPTION OF THE INVENTION

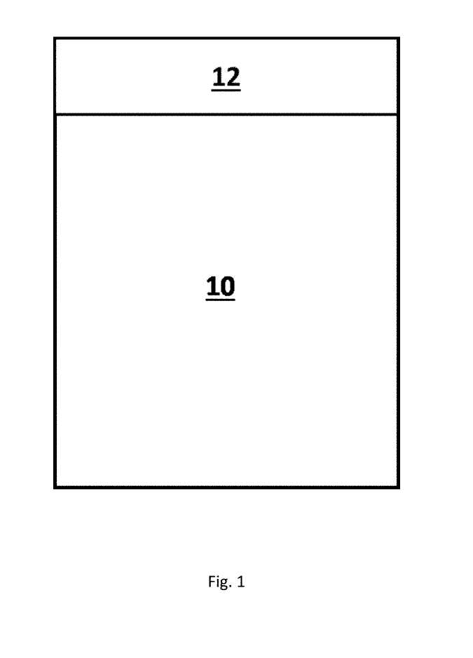

Embodiments of the disclosure relate to polycrystalline diamond compact (PDC) cutter having a metallic coating. The PDC cutter comprises a layer or “table” of polycrystalline diamond (PCD) materials as a cutting element and a cemented carbide body as a cutter substrate. The PDC cutter is formed by sintering and bonding together relatively small diamond grains under conditions of high temperature and high pressure (HTHP) in the presence of a catalyst to form a table of polycrystalline diamond materials on a cutter substrate. The cutter substrate may comprise a cemented carbide material such as cobalt-sintered tungsten carbide. In such the instances, the cobalt (or other catalyst material) in the cutter substrate may diffuse into the diamond grain compacts during sintering and serve as the catalyst material for forming the inter-granular diamond-to-diamond bonds, and the resulting PCD table, from the diamond grains. In other methods, powdered catalyst material may be mixed with the diamond grains prior to sintering the grains together in an HTHP process. Alternatively, a PDC cutter can be formed by brazing an unbacked PCD table onto a cemented material substrate. The unbacked PCD can be formed by sintering individual diamond particles together in an HTHP process in the presence of a catalyst that promotes diamond-diamond bonding, as described previously. FIG. 1 schematically shows a cross sectional view of a PDC cutter. The PDC cutter comprises a cemented carbide body 10 as a supporting substrate and a PCD table 12 as a cutting element, such as those discussed above.

Embodiments of the disclosure relate to PDC cutter having a coating of carbide-forming metals/alloys. The PDC cutter consists of an unleached or leached PCD table and a cemented carbide body. The coating covers at least all of the exterior surfaces of the PCD table of the PDC cutter, and it may also extend over partially or entirely the exterior surfaces of the cemented carbide body. The coating comprises at least one of carbide-forming metals selected from titanium (Ti), niobium (Nb), zirconium (Zr), vanadium (V), tantalum (Ta), hafnium (Hf), chromium (Cr), tungsten (W), molybdenum (Mo), or the alloys containing at least one of these metals. Interface between the coating and the PDC cutter has a metallurgical bonding, which is characterized by the formation of a carbide during deposition processes, additional heat treatments, or subsequent brazing operations when joining to a tool body.

According to the disclosure, the coating acts as a protective layer for a PDC cutter, especially for its PCD table, which experiences thermal attack during brazing operations and cutting applications where a high temperature is generated, causing its oxidation and graphitization of diamond. The coating has a metallurgical bonding with the PDC cutter. The coating may be either single layer or multilayers. The coating layer adjacent to the PDC cutter must comprise at least one of the carbide-forming metals selected from Ti, Nb, Zr, V, Ta, Hf, Cr, W, Mo, or the alloys containing at least one of these metals. If the coating consists of multilayers, the outermost coating layer consists of metals or alloys having a good oxidation resistance including nickel (Ni), tungsten (W), tantalum (Ta), titanium (Ti), chromium (Cr), iron (Fe), molybdenum (Mo), manganese (Mn), silver (Ag), copper (Cu), gold (Au), platinum (Pt), palladium (Pd), or the alloys containing at least one of these metals.

According to the disclosure, the selection of the carbide-forming metals or alloys as a coating layer adjacent to a PDC cutter is for generating a metallurgical bonding, i.e., formation of a carbide at the interface between the coating and the PDC cutter. The formation of the carbide at the interface between the coating and the PDC cutter results from a reaction between the carbide-forming metal elements in the coating and carbon atoms in the PDC cutter at high temperatures. Such the reaction can occur during deposition processes, additional heat treatments, or subsequent brazing operations when joining the PDC cutter to a cutting tool body.

According to this disclosure, a heat treatment is employed to form a carbide at interface between the coating and the PDC cutter. The heat treatment is conducted in an inert gas protective furnace at 450° C.-850° C. for 5 minutes to 120 minutes. The heat treatment can be performed after depositing the whole coating layers or just after depositing a carbide-forming metal/alloy layer in case of a multilayer coating.

According to this disclosure, the metallic coating thickness is in a range of 0.04 μm-100 μm, preferably 0.1 μm-20 μm.

According to this disclosure, the PDC cutter is either an unleached or leached PDC cutter. The unleached PDC cutter refers to a conventional PDC cutter whose PCD table comprises inter-bonded diamond grains and catalytic metals/alloys such as cobalt. Its thermal stability is not higher than 750° C. The leached PDC cutter refers to a kind of thermally stable PDC (TSPDC) cutters whose PCD table comprises inter-bonded diamond grains, and none or a reduced amount of catalytic metals/alloys that are leached out using acids. The leached PDC cutter usually contains none or a reduced amount of catalytic metals/alloys only around the outermost surface layer of its PCD table, since a completely leached PCD is very brittle. The leached PDC cutter has better performance at high temperatures, whose thermal stability may be up to 1200° C.

According to this disclosure, the cemented carbide body substrate of a PDC cutter is usually referred to as sintered tungsten carbide compacts, i.e., the composite materials of tungsten carbide particles and metal/alloy binders such as iron, nickel, cobalt, or their alloys. The sintered tungsten carbide compacts are either straight grade sintered tungsten carbide composites in which tungsten carbide is the sole carbide constituent, or those straight grades combined with varying proportions of other carbides such as titanium carbide (TiC), tantalum carbide (TaC), niobium carbide (NbC), etc.

According to this disclosure, the coating covers all of the exterior surfaces of a PCD table of a PDC cutter. Furthermore, the coating may extend partially or completely over a cemented carbide body substrate. The coating on the cemented carbide body substrate can improve its bonding strength with a tool substrate and mitigate oxidation damages during brazing operations and cutting applications as well.

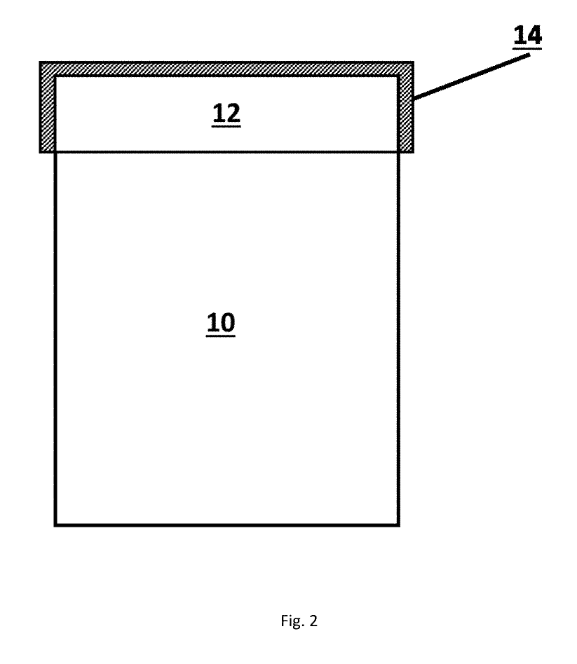

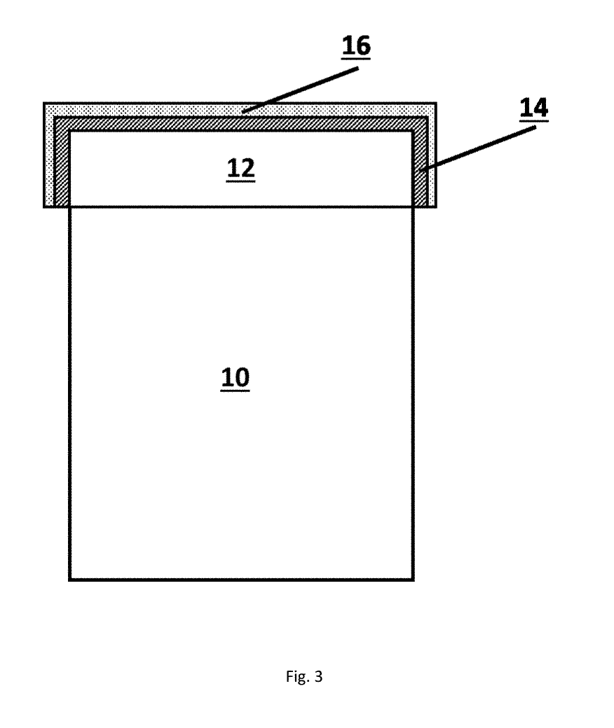

Referring to FIG. 2, another embodiment of a PDC cutter having a coating over its PCD table in accordance with the present disclosure is shown. FIG. 2 schematically shows a cross sectional view of a PDC cutter having a coating. As shown, the PCD table 12 has a carbide-forming metal/alloy coating 14 over its exterior surfaces. The cemented carbide body 10 is the substrate of the PCD table 12. It should be apparent that the layer illustrated in FIG. 2 is exaggerated in thickness for purposes of illustration and in practice it is extremely thin. The similar illustrations are also in FIGS. 3-5.

Referring to FIG. 3, another embodiment of a PDC cutter having a multilayer coating over its PCD table in accordance with the present disclosure is shown. FIG. 3 schematically shows a cross sectional view of a PDC cutter having a two-layer coating. As shown, the PCD table 12 has the carbide-forming metal/alloy coating 14 as an inner layer and an oxidation-resistant metal/alloy coating 16 as an outer layer over its exterior surfaces. The cemented carbide body 10 is the substrate of the PCD table 12.

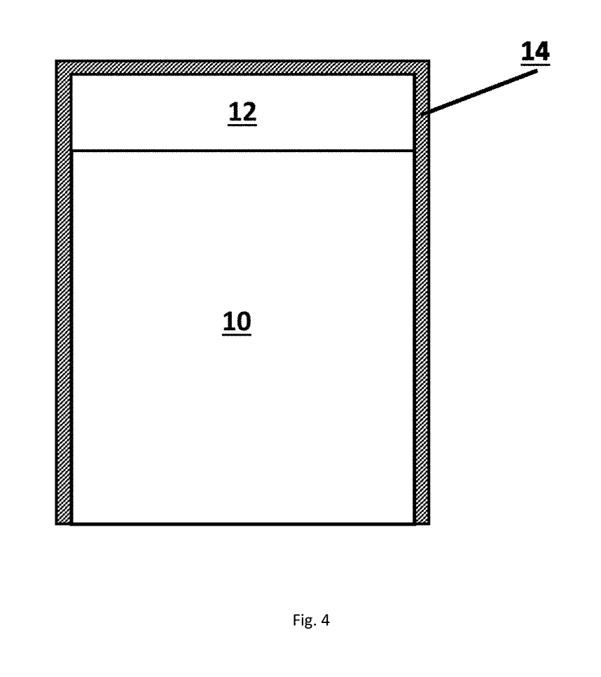

Referring to FIG. 4, another embodiment of a PDC cutter having a coating over its PCD table and a portion of a cemented carbide body in accordance with the present disclosure is shown. FIG. 4 schematically shows a cross sectional view of a PDC cutter having a metallic coating. As shown, the PCD table 12 has the carbide-forming metal/alloy coating 14 over its exterior surfaces and the cemented carbide body 10 has the carbide-forming metal/alloy coating 14 over its side surfaces.

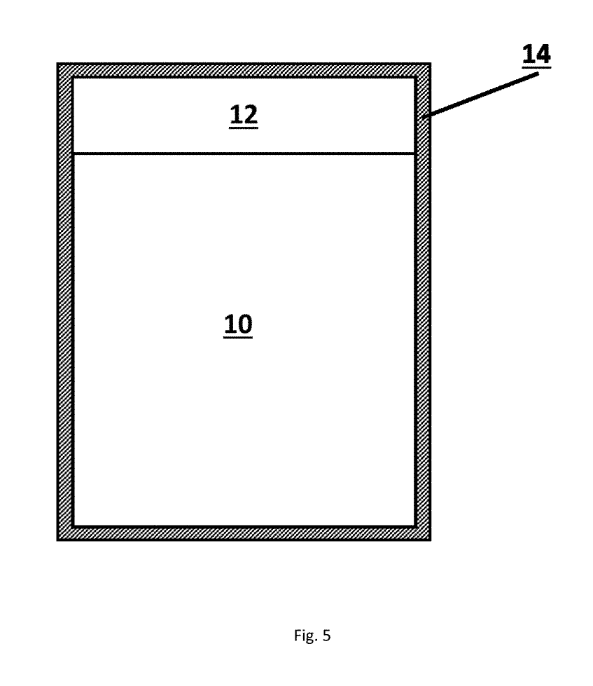

Referring to FIG. 5, another embodiment of a PDC cutter having a coating over its exterior surfaces in accordance with the present disclosure is shown. FIG. 5 schematically shows a cross sectional view of a PDC cutter having a metallic coating. As shown, the PDC cutter including the cemented carbide body 10 and the PCD table 12 has the carbide-forming metal/alloy coating 14 over all of its exterior surfaces.

According to this disclosure, the coating may cover the exterior surfaces of a PDC cutter partially or completely. Furthermore, the PDC cutter may have different coatings at different locations. For example, an upper portion of a PDC cutter has a titanium coating and its lower portion has a chromium coating.

According to this disclosure, the PDC cutters may have various geometric shapes such as cylinders, cones, cubes, cuboids, etc.

According to the disclosure, coating processes can be one of PVD, CVD, TD, electrolytic plating, electroless plating, other deposition methods, or their combinations.

PVD is conducted at a relatively low temperature, usually below 500° C. A metallurgical bonding interface containing a carbide may not be formed during the deposition processes. But, additional heat treatments, or subsequent brazing operations when joining to a tool body may form a metallurgical bonding interface containing a carbide at the interface between the coating and the PDC cutter.

CVD technique utilizes a high temperature process, up to 1000° C. Thus, a metallurgical bonding interface containing a carbide is expected to form during the deposition processes. However, processing parameters must be selected carefully, so as to avoid any thermal damages to a PDC cutter during the deposition processes.

TD techniques include salt bath immersion and pack cementation methods. They are conducted at high temperatures between 500° C. and 1250° C. Thus, a metallurgical bonding interface containing carbide may be formed during the coating processes. Likely, processing parameters must be selected carefully, so as to avoid any thermal damages to a PDC cutter during the deposition processes.

Electrolytic plating and electroless plating are performed in an electrolyte solution at a temperature less than 100° C. A part to be plated must be an electric conductor. Therefore, Electrolytic plating and electroless plating could not be applied directly to a PDC cutter, as the PCD table of a PDC cutter is not electrically conductive. The plating methods are only suitable to coat a PDC with a prior metal coated layer. That is, electrolytic plating or electroless plating is used to form a metallic coating layer over a prior metallic coating on a PDC cutter to make a multilayer coating.

Examples are provided below to illustrate the working of the embodiments, but such examples are by no means considered restrictive.

### Example 1: Coating a PDC Cutter by PVD—Ion Plating

A cylindrical PDC cutter of 16 mm diameter and 12.5 mm height was used for experiment. The PDC cutter consists of an unleached PCD table of 2 mm height and a sintered tungsten carbide body of 10.5 mm height as a substrate. The PDC cutter was subjected to ion plating processing to deposit Cr over all the exterior surfaces of the PCD table and the side surfaces of the sintered tungsten carbide body. Ion plating is one of PVD processes that is also referred to as ion assisted deposition. The coating metal is Cr. The PDC cutter was rinsed ultrasonically in acetone, dried, and then put into a chamber of an ion plating machine. The process was performed in vacuum. The deposition temperature is 350° C. and the deposition time is 1.5 hours. The coating thickness is about 2 μm.

### Example 2: Coating a PDC Cutter by Electrolytic Plating

The PDC cutter with the Cr coating of example 1 was further coated with Ni by electrolytic plating. Electrolyte solution consists of 280 g/L NiSO₄.6H₂O, 30 g/L NiCl₂.6H₂O, 35 g/L H₃BO₃, and 2 g/L C₉H₆O₂. The PH value of the electrolyte solution is 4. Anode is a nickel plate and cathode is the PDC cutter to be plated. Cathode current density is about 5 A/dm². The temperature of the plating bath is 55° C. The plating time is 30 min. The Ni coating with a thickness of about 20 μm covers over all the exterior surfaces of the PCD table and the side surfaces of the sintered tungsten carbide. The coating has two layers. The inner coating layer is Cr and the outer coating layer is Ni.

### Example 3: Heat Treatment of Coated PDC Cutter

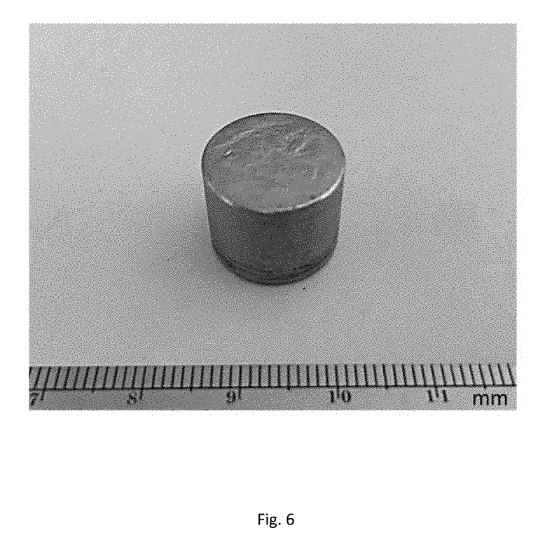

The PDC cutter with the two layer coating of example 2 was subject to heat treatment. The heat treatment was performed in an electric resistance furnace under flowing Ar. The heating rate is 10° C./min. The predetermined holding temperature is 630° C. and the predetermined holding time is 1 hour. The PDC cutter was cooled in the furnace by turning off the power while keeping Ar flowing. The heat treatment is to achieve a metallurgical bonding between the PCD table of the PDC cutter and the coating layer. FIG. 6 shows the PDC cutter with the two layer coating and subjected to the heat treatment. The coating is continuous, crack free, and impermeable. The coating would isolate the PCD table of the PDC cutter from oxygen in atmosphere during brazing operations and cutting services. It would protect the PCD table from thermal degradations such as oxidation and graphitization of diamond. At the same time, the coating on the side surfaces of the sintered tungsten carbide body would improve its brazing capability and enhance its bonding strength with a tool body.

According to this disclosure, the PDC cutters with the metallic coatings are mounted to a cutting tool body as cutting elements, such as drilling bits, reamers, etc. The joining methods include mechanical securing methods or brazing operations. Although the mechanical securing methods eliminate thermal attacks during joining, the PCD tables of PDC cutters still encounter risk of thermal degradation during cutting services where high temperatures is generated.

According to this disclosure, the selected metallic coatings on a PDC cutter are a protective coating. The coatings can prevent the PDC cutter, especially the PCD table from oxidation and degradation during brazing operations and cutting applications where high temperatures are generated, such as graphitization of diamond. No matter whether they are single layer or multilayer, the coatings have a metallurgical bonding with the PDC cutter, which is characterized by formation of a carbide at their interface with or without an aid of additional heat treatments, and a better oxidation resistance. Furthermore, the coatings would impart a better brazing capability to a PDC cutter, if they extend over a brazing portion of the PDC cutter.

Advantageously, embodiments of the present disclosure provide a PDC cutter with a metallic coating. The formation of the coating is through one of PVD, CVD, TD, electrolytic plating, electroless plating, or any other deposition methods, or their combinations. The metallic coating would mitigate thermal damages of the PDC cutter, especially PCD table during brazing operations and cutting applications, improve brazing capability, and enhance bonding strength. The processing methods are convenient, cost-effective, and suitable for mass production.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiments, methods, and examples, but by all embodiments and methods within the scope and spirit of the invention as claimed.

1. A polycrystalline diamond compact cutter comprising:
a cemented carbide body as a supporting substrate;
an unleached or leached polycrystalline diamond table as a cutting element; and
a coating covering all of the exterior surfaces of the polycrystalline diamond table, wherein the coating consists of at least one of carbide-forming metals selected from Ti, Nb, Zr, V, Ta, Hf, Cr, W, Mo, or the alloys containing at least one of these metals.

2. The polycrystalline diamond compact cutter as defined in claim 1, wherein the coating has a metallurgical bonding with the polycrystalline diamond table which is characterized by formation of a carbide at their interface.

3. The polycrystalline diamond compact cutter as defined in claim 2, wherein the metallurgical bonding between the coating and the polycrystalline diamond compact cutter, i.e., formation of a carbide, is developed during deposition processes or heat treatments.

4. The polycrystalline diamond compact cutter as defined in claim 3, wherein the coating is subjected to heat treatments of between 450° C. and 850° C. for 5 minutes-120 minutes.

5. The polycrystalline diamond compact cutter as defined in claim 1, wherein the coating extends over a portion of the exterior surfaces of the cemented carbide body.

6. The polycrystalline diamond compact cutter as defined in claim 1, wherein the coating extends over all of the exterior surfaces of the cemented carbide body.

7. The polycrystalline diamond compact cutter as defined in claim 1, wherein the coating may be a single layer or multilayer coating.

8. The polycrystalline diamond compact cutter as defined in claim 7, wherein the multilayer coating has an outer layer of metals or alloys comprising at least one of Ni, W, Ta, Ti, Cr, Fe, Mo, Mn, Ag, Cu, Au, Pt, or Pd.

9. The polycrystalline diamond compact cutter as defined in claims 1, 7, and 8, wherein the coating has a thickness of 0.04 μm-100 μm.

10. Methods of making the polycrystalline diamond compact cutter with the metallic coating according to claim 1, comprising at least one of physical vapor deposition, chemical vapor deposition, thermoreactive deposition and diffusion, electrolytic plating, or electroless plating.

11. Methods of joining the polycrystalline diamond compact cutter with the metallic coating according to claim 1 to a cutting tool, comprising one of mechanical securing methods and brazing operations.

12. The polycrystalline diamond compact cutter on the cutting tool as defined in claim 11, wherein a metallurgical bonding between the coating and the polycrystalline diamond compact cutter, i.e., formation of a carbide, is developed during deposition processes, heat treatments, or brazing operations.
